(19) United States
(12) Patent Application Publication
(10) Pub. No.: US 2007/0119620 A1
(43) Pub. Date: May 31, 2007

(54) Flexible circuit shields

(76) Inventors: Jose F. Rodriguez, Miami, FL (US); Julio C. Castaneda, Coral Springs, FL (US); Bach L. Nguyen, Lauderhill, FL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(21) Appl. No.: 11/289,002

(22) Filed: Nov. 29, 2005

(51) Int. Cl. H05K 9/00

(52) U.S. Cl. 174/378

(57) ABSTRACT

The invention concerns a method (600) and systems (200, 400, 500) for shielding at least one electrical component (104) by using a flexible shielding circuit (102). In one arrangement, the method can include the steps of mounting (604) the electrical component on a first portion (202) of the flexible shielding circuit and covering (606) at least one exposed surface of the electrical component with a second portion (204) of the flexible shielding circuit. Additionally, the method can also include the step of selectively securing (608) the second portion to the first portion with a conductive adhesive (206).

### BACKGROUND OF THE INVENTION

1. Field of the Invention

The present invention relates in general to the field of flexible circuits, and more particularly to the field of shielding electrical components in flexible circuits.

2. Description of the Related Art

A flexible circuit includes a flexible material that has one or more metal circuit patterns. The flexible material may be single-layered or multi-layered, depending on the number of metal circuit patterns that are insulated from one another by flexible polymer films. The metal circuit patterns include electrical signal paths and ground planes that are embedded in the flexible material. The metal circuit patterns can be interconnected through vias. As is known in the art, a via refers to a metal-plated through hole that connects two or more metal circuit patterns, allowing signals to pass through the flexible material to the signal layers or the ground planes. Several electrical components that can be passive and/or active may be mounted on the flexible circuit. Passive components refer to devices that have a minimal impact on the electrical signals passing through them. Examples of passive components include, but are not limited to, resistors, capacitors and inductors. Active components refer to devices with gains, or which direct the flow of the current. Examples of active components include, but are not limited, to transistors and thyristors.

The electrical components used in the flexible circuits may produce electromagnetic interference (EMI) and radio frequency interference (RFI). Electromagnetic interference refers to interference caused by the electromagnetic radiation emitted by electrical devices. RFI refers to interference due to electromagnetic radiation in the radio frequency spectrum emitted by electrical devices. These interferences induce unwanted signals in other circuits, which may cause electronic failure and degrade the performance of the other circuits. Hence, shielding is required to block EMI and RFI in many electrical devices, including those that contain flexible circuits. Generally, these devices are positioned on printed circuit boards and are covered with metal shields. Because the shields are made of metal, a gap must be maintained between the shields and the components. This gap and the thickness of the shields and the PCB add to the overall height of a device housing them.

### SUMMARY OF THE INVENTION

The present invention concerns a method for shielding at least one electrical component on a flexible shielding circuit. The electrical component may produce electromagnetic interference (EMI) or radio frequency interference (RFI). The flexible shielding circuit can include one or more signal layers that are separated by insulating layers and at least a first portion and a second portion.

The method can include the steps of mounting the electrical component on the first portion of the flexible shielding circuit, covering at least one exposed surface of the electrical component that is mounted on the first portion with the second portion of the flexible shielding circuit, and selectively securing the second portion to the first portion. In accordance with an embodiment of the inventive arrangements, the second portion can provide shielding for the electrical component.

In one arrangement, covering the exposed surface of the electrical component can include folding the second portion of the flexible shielding circuit over the electrical component. This folding process can include bending the second portion in a manner such that a loop can be formed by a part of the second portion. Selectively securing the second portion to the first portion can include joining the ends of the loop with a conductive adhesive.

In another arrangement, covering the exposed surface of the electrical component can include covering the exposed surface in a manner such that a gap can be formed between the exposed surface of the electrical component and the second portion covering the exposed surface. Also, covering the exposed surface can include securing the second portion covering the exposed surface to the exposed surface with an adhesive. Additionally, the method can also include the steps of mounting another electrical component on top of the second portion shielding the electrical component and routing signals from one part of the electrical component to another part of the electrical component, or another electrical component, through signal layers, without interfering with a ground plane in the first portion.

The present invention also concerns a flexible shielding circuit. The flexible shielding circuit can include at least one electrical component that may produce electromagnetic interference or radio frequency interference and a flexible circuit that may containing one or more signal layers. As an example, the flexible circuit can include a first portion and a second portion in which the electrical component can be mounted on the first portion. In addition, the second portion can cover at least one exposed surface of the electrical component and can be selectively secured to the first portion. As a result, the second portion may provide shielding for the electrical component.

In one arrangement, the second portion of the flexible circuit can be folded over the electrical component and bent in a manner such that a part of the second portion can form a loop. As an example, the ends of the loop can be joined by a conductive bond. The flexible shielding circuit may also include an adhesive that can secure the second portion to the exposed surface of the electrical component. In another arrangement, there may be a gap between the exposed surface of the electrical component and the second portion that can cover the exposed surface.

In yet another arrangement, signals may be routed from one part of the electrical component to another part of the electrical component or some other electrical component through the signal layer in the second portion. The first portion of the flexible circuit may include a ground plane, and the signals may be routed through the signal layer of the second portion without interfering with the ground plane in the first portion. The flexible shielding circuit can also include another electrical component mounted on top of the second portion of the flexible shielding circuit. As an example, the flexible shielding circuit can be part of a mobile communications unit having a transmitter or a receiver or both. At least a portion of the flexible circuit can include an outer, non-conductive layer that may surround the signal layers.

### BRIEF DESCRIPTION OF THE DRAWINGS

The features of the present invention, which are believed to be novel, are set forth with particularity in the appended claims. The invention, together with further objects and advantages thereof, may best be understood by reference to the following description, taken in conjunction with the accompanying drawings, in the several figures of which like reference numerals identify like elements, and in which:

FIG. 1 illustrates a side view of an example of an electrical component mounted on a flexible shielding circuit, in accordance with an embodiment of the inventive arrangements;

FIG. 2 illustrates a cross-sectional diagram of an example of a flexible shielding circuit used for shielding an electrical component, in accordance with an embodiment of the inventive arrangements;

FIG. 3 illustrates an isometric view of the flexible shielding circuit portrayed in FIG. 2, in accordance with an embodiment of the inventive arrangements;

FIG. 4 illustrates a cross-sectional diagram of an example of a multi-layered flexible shielding circuit used for shielding an electrical component, in accordance with an embodiment of the inventive arrangements;

FIG. 5 illustrates an isometric view of shielding portrayed in FIG. 4, in accordance with an embodiment of the inventive arrangements; and

FIG. 6 illustrates a flowchart of a method for shielding an electrical component using flexible shielding circuit, in accordance with an embodiment of the inventive arrangements.

### DETAILED DESCRIPTION OF THE INVENTION

While the specification concludes with claims defining the features of the invention that are regarded as novel, it is believed that the invention will be better understood from a consideration of the following description in conjunction with the drawing figures, in which like reference numerals are carried forward.

As required, detailed embodiments of the present invention are disclosed herein. However, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting, but rather to provide an understandable description of the invention.

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language).

The invention concerns a method and system for shielding an electrical component by using a flexible shielding circuit. The electrical component may produce electromagnetic interference (EMI) or radio frequency interference (RFI). The flexible shielding circuit can include one or more signal layers. In one arrangement, the method can include the steps of mounting the electrical component on a first portion of the flexible shielding circuit, covering an exposed surface of the electrical component that is mounted on the first portion with a second portion of the flexible shielding circuit, and selectively securing the second portion to the first portion. This process can provide EMI and RFI shielding for the electrical component without substantially increasing the thickness of a device housing the electrical component and the flexible shielding circuit. As an example, the flexible shielding circuit can be part of a mobile communications unit having a transmitter or a receiver or both.

In one arrangement, the method can also include the steps of folding the second portion of the flexible shielding circuit over the electrical component, bending the second portion such that a loop is formed by a part of the second portion, and joining the ends of the loop with a conductive adhesive. In addition, the method can include the steps of mounting another electrical component on top of the second portion, and routing signals from one part of the electrical component to another part of the electrical component or some other electrical component, through signal layers in the second portion, without interfering with a ground plane in the first portion. As such, the invention can provide shielding for electrical components and can also pass electrical signals.

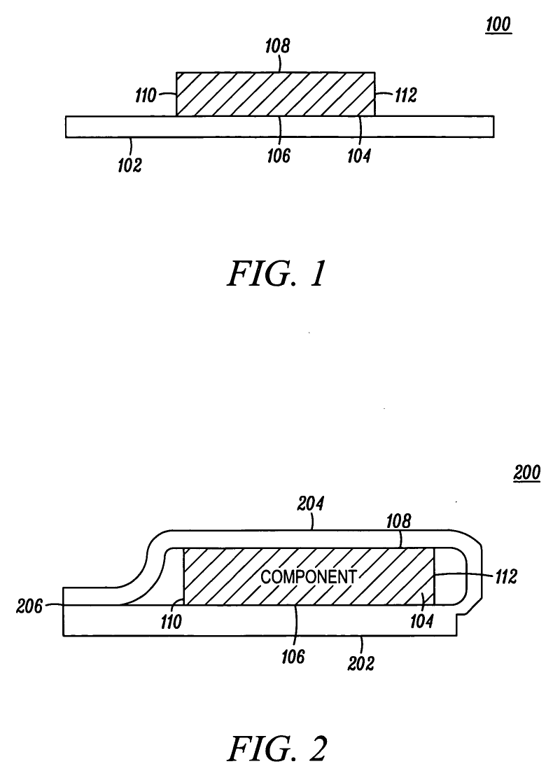

Referring to FIG. 1, a side view 100 of an electrical component 104, mounted on a flexible shielding circuit 102, is shown. It will be apparent to a person skilled in the art that the electrical component 104 can have various shapes. For example, the electrical component 104 can have the shape of a cube. In this case, the electrical component 104 has six faces or surfaces. In FIG. 1, only four surfaces 106, 108, 110 and 112 can be seen. The surface 106 of the electrical component 104 can be mounted on the flexible shielding circuit 102 and secured to the circuit 102 using any suitable means or process, such as through soldering. Surface 108, surface 110, and surface 112 are the exposed surfaces of the electrical component 104. Surface 108 is the top exposed surface of the electrical component 104. Any one of the exposed surfaces 108,110 and 112 and the surface 106 of the electrical component 104 may emanate electromagnetic radiation. As an example, the electrical component 104 may be an integrated circuit (IC), although other suitable components are within contemplation of the inventive arrangements.

Referring to FIG. 2, a cross-sectional diagram of a system 200 for shielding an electrical component 104 by using a flexible shielding circuit 102 is shown. In one arrangement, the system 200 can include a first portion 202 of the flexible shielding circuit 102, a second portion 204 of the flexible shielding circuit 102, the electrical component 104, and a conductive adhesive 206, which can help secure the second portion 204 to the first portion 202. Examples of the conductive adhesive 206 can include, but are not limited to, solder and anisotropic conducting films (ACF), although any other suitable conductive adhesive may be used here.

The surface 106 of the electrical component 104 can be mounted on the first portion 202 in accordance with any suitable procedure for securing an electrical device to a flexible circuit. Both the first portion 202 and the second portion 204 may be part of the flexible shielding circuit 102. In other words, the two portions of the flexible shielding circuit 102 may be in continuum, although they can also be separate parts joined together through any suitable process.

In one arrangement, the second portion 204 of the flexible shielding circuit 102 can be folded over the electrical component 104 to cover, for example, the exposed surfaces of the electrical component 104. The electrical component 104 can then be shielded by securing the second portion 204 of the flexible shielding circuit 102 to the first portion 202 with the conductive adhesive 206.

In one arrangement, the second portion 204, covering the exposed surfaces of the electrical component 102, can be selectively secured to the exposed surfaces by using an adhesive. In another arrangement, the second portion 204 can be merely positioned over the exposed surfaces of the electrical component 104 such that there may be a slight gap between the second portion 204 and the exposed surfaces.

Though the system 200 is shown to include only the electrical component 104, the system 200 can include a plurality of electrical components that are shielded by the flexible shielding circuit 102. For example, a plurality of electrical components 104 can be mounted next to one another on the first portion 202 of the flexible shielding circuit 102, and second portions 204 can be used to shield these components 104. Moreover, one or more electrical components 104 can be mounted on the top surface of the second portion 204, and another second portion 204 can be folded over these components 104 and secured to the second portion 204 on which the components 104 are mounted. This process can allow for the stacking of electrical components 104, and each of them can be shielded by a second portion 204.

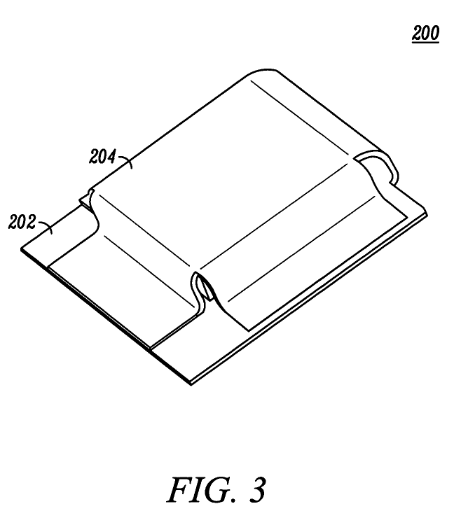

Referring to FIG. 3, an isometric view of the system 200, discussed in FIG. 2, is shown. The second portion 204 extends from the first portion 202 and can cover the surfaces of the electrical component 104. The second portion 204 can include one or more flaps 205, each of which can be secured to the first portion 202, such as with a conductive adhesive (see FIG. 2). In view of this exemplary design, the second portion 204 can shield the top and the sides of the electrical component 104.

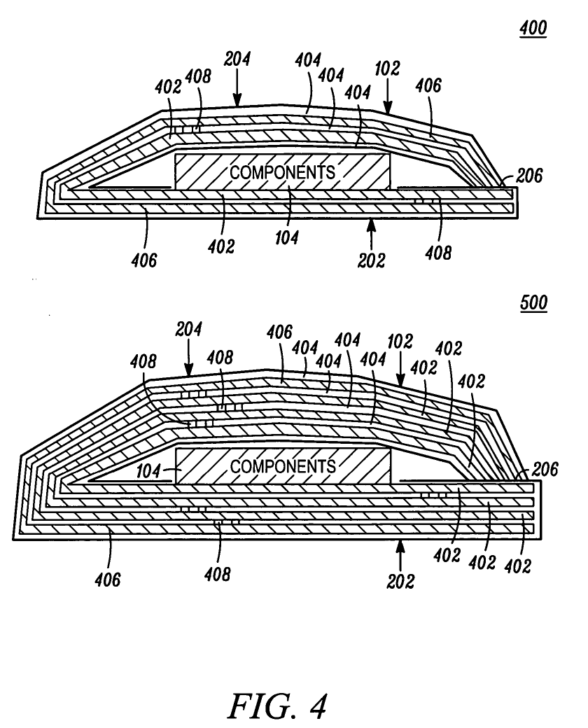

Referring to FIG. 4, a cross-sectional diagram of a system 400 and a system 500 for shielding an electrical component 104 by using a flexible shielding circuit 102, in accordance with another inventive arrangement of the present invention, is shown. In one arrangement, the flexible shielding circuit 102 of the system 400 and the system 500 can include multiple signal layers. In particular, the system 400 can have a two-layer flexible shielding circuit 102 and the system 500 can have a four-layer flexible shielding circuit 102, although it is understood that the invention is in no way limited to these two examples.

As an example, in the flexible shielding circuit 102 of both systems 400, 500, a first portion 202 and a second portion 204 can include one or more signal layers 402, one or more insulating layers 404, and one or more ground planes 406. It is important to note that the invention is not limited to the layer layout that is illustrated here in FIG. 4, as other suitable arrangements are within contemplation of the invention. In one embodiment, the signal layers 402 can be selectively connected to each other and the ground plane(s) 406 through vias 408.

While covering the electrical component 104, the second portion 204 can be folded in a manner so that a loop 410 is formed, similar to what is shown in FIG. 3. As can be seen and as explained earlier, the second portion 204 can be secured to the first portion 202 with a conductive adhesive 206. In addition to the vias 408 and as will be appreciated by those of skill in the art, the conductive adhesive 206 can be used to facilitate the transfer of electrical signals between the signals layers 402 and the ground plane(s) 406. In view of the ground plane(s) 406, the flexible shielding circuit 102 can serve as a suitable shield for the electrical component 104.

The external layer of the flexible shielding circuit 102 can be an insulating layer 404 or material, which, as those of skill in the art can appreciate, can allow the second portion 204 to be secured to the top of the electrical component 104, such as with an adhesive. Accordingly, there may be little or no space between the top of the component 104 and the circuit 102. This can lower the overall height of the systems 400, 500. As an alternative, the second portion 204 can be merely placed over the top of the electrical component 104. In this arrangement, a small gap may exist between the top of the electrical component 104 and the circuit 102. In either alternative, the overall height of the systems 400, 500 is reduced because the flexible shielding circuit 102 is thinner than a conventional metal shielding arrangement.

Although the flexible shielding circuit 102 may be mounted on a printed circuit board (PCB), it is not necessary to do so. That is, the flexible shielding circuit 102 may stand on its own. This feature can enable the circuit 102 to be implemented in electrical devices or portions of electrical devices that do not have a PCB, such as the flip portion of a cellular telephone.

In another arrangement, signals can be routed from one part of the electrical component 104 to, for example, another part of the electrical component 104 through the signal layers 402 without interfering with the ground plane 406. Those of skill in the art can appreciate the utility of this feature. In addition, the vias 408 and the conductive adhesive 206 can assist in the routing of these signals.

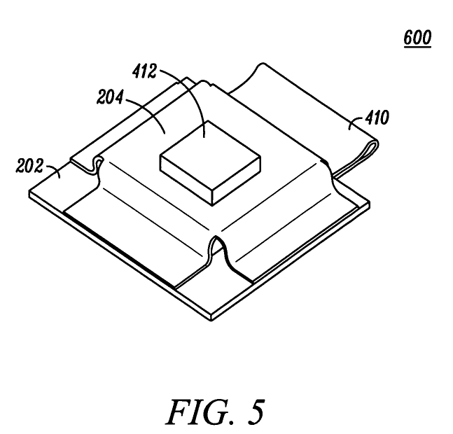

Referring to FIG. 5, an isometric view of a system 600 is shown. This system 600 is similar to the embodiments previously described. Here, however, in contrast with the arrangement shown in FIG. 2, the loop 410 can be secured to the first portion 202, such as with an adhesive, including the conductive adhesive 206 of FIG. 2. This process can eliminate or at least reduce the gaps that may be created when the loop 410 is formed, which can result in even better shielding for the electrical component 104.

In one of the inventive arrangements, another electrical component 412 can be mounted on the second portion 204 of the flexible shielding circuit 102, in a manner that is similar to the mounting discussed with reference to FIG. 2. This feature can allow for the stacking of electrical components 104 that can be properly shielded but without increasing the height of the stack beyond an unacceptable level.

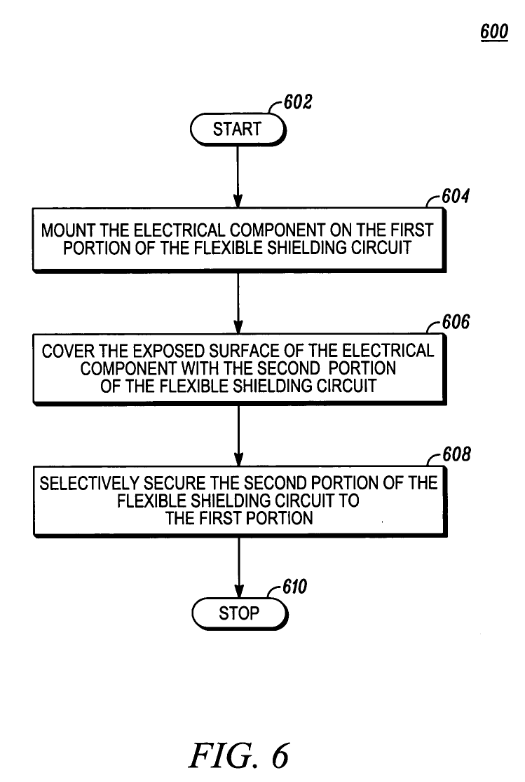

The inventive arrangements discussed above can be implemented by using a method 600 for shielding an electrical component 104, using the flexible shielding circuit 102, as shown in FIG. 6. To describe the method 600, reference will be made to FIGS. 1-5, although it is understood that the method 600 can be implemented with reference to any other suitable arrangement of the present invention. In addition, the method 600 can contain a greater or a fewer number of steps than shown in FIG. 6. Several suitable examples of method 600 will be presented below.

In one arrangement, the method 600 can include one or more method steps for shielding the electrical component 104 by using the flexible shielding circuit 102. At step 602, the method 600 can begin. At step 604, the electrical component 104 can be mounted on the first portion 202 of the flexible shielding circuit 102. At step 606, the exposed surfaces of the electrical component 104, mounted on the first portion 202 of the flexible shielding circuit 102, can be covered with the second portion 204 of the flexible shielding circuit 102. In another arrangement of the present invention, the second portion 204, covering the exposed surfaces of the electrical component 104, can be secured to the exposed surfaces with an adhesive. In yet another arrangement of the present invention, the electrical component 104 can be covered with the second portion 204, such that a gap is formed between the exposed surfaces of the electrical component 104 and the second portion 204 that is covering the exposed surfaces of the electrical component 104.

In another arrangement of the present invention, at step 606, the second portion 204 can be folded to cover the exposed surfaces of the electrical component 104. In yet another arrangement, at step 606, while folding the second portion 204 for covering the electrical component 104 mounted on the ground plane 406 of the first portion 202 of the flexible shielding circuit 102, the second portion 204 can be bent in a manner such that the loop 410 is formed. The ends of the loop 410 can be selectively secured to each other with the conductive adhesive 206.

In yet another arrangement, the method 600 can include the step of mounting another electrical component 412 on top of the second portion 204 covering the electrical component 104 that is mounted on the first portion 202 of the flexible shielding circuit 102. In still another arrangement, the method 600 can include the steps of routing signals from one part of the electrical component 104 to another part of the electrical component 104 or to the electrical component 412 through the signal layers 402 and the vias 408 connecting the signal layers of the second portion 204, without interfering with the ground plane 406 of the first portion 202 of the flexible shielding circuit 102.

At step 608, in one arrangement of the invention, the second portion 204 can be selectively secured to the first portion-202 with the conductive adhesive 206. In another arrangement to the invention, at step 608, the second portion 204 of the flexible shielding circuit can be selectively secured to the first portion 202 with the conductive adhesive 206. In yet another arrangement, the electrical component 412 mounted on the second portion 204, can be shielded by using the flexible shielding circuit 102 or some other flexible shielding circuit. At step 610, the method 600 can end.

Therefore, it should be clear from the preceding disclosure that the present invention provides a system and a method for shielding at least one electrical component by using flexible shielding circuits that provide better flexibility and compact shielding. While the preferred embodiments of the invention have been illustrated and described, it will be clear that the invention is not so limited. Numerous modifications, changes, variations, substitutions and equivalents will occur to those skilled in the art without departing from the spirit and scope of the present invention as defined by the appended claims.

What is claimed is:

1. A method for shielding at least one electrical component on a flexible shielding circuit, the electrical component produces electromagnetic interference or radio frequency interference, the flexible shielding circuit including one or more signal layers and at least a first portion and a second portion and both the first portion and the second portion include one or more of the signal layers, the method comprising:
mounting the electrical component on the first portion of the flexible shielding circuit;
covering at least one exposed surface of the electrical component that is mounted on the first portion with the second portion of the flexible shielding circuit; and
selectively securing the second portion of the flexible shielding circuit to the first portion, wherein the second portion provides shielding for the electrical component.

2. The method according to claim 1, wherein covering the exposed surface of the electrical component comprises folding the second portion of the flexible shielding circuit over the electrical component.

3. The method according to claim 2, wherein folding the second portion of the flexible shielding circuit comprises bending the second portion in a manner such that a loop is formed by a part of the second portion about which the second portion is folded.

4. The method according to claim 3, wherein selectively securing the second portion to the first portion comprises joining the ends of the loop with a conductive adhesive.

5. The method according to claim 1, wherein covering the exposed surface of the electrical component comprises covering the exposed surface in a manner such that a gap is formed between the exposed surface of the electrical component and the second portion covering the exposed surface.

6. The method according to claim 1, wherein covering the exposed surface comprises securing the second portion covering the exposed surface to the exposed surface with an adhesive.

7. The method according to claim 1, further comprising routing signals from one part of the electrical component to another part of the electrical component or some other electrical component through the signal layer in the second portion without interfering with a ground plane in the first portion.

8. The method according to claim 1, further comprising mounting one or more electrical components on top of the second portion of the flexible shielding circuit.

9. A flexible shielding circuit, comprising:
at least one electrical component that produces electromagnetic interference or radio frequency interference; and
a flexible circuit, containing one or more signal layers, wherein the flexible circuit comprises:
a first portion, wherein the electrical component is mounted on the first portion; and
a second portion, wherein the second portion covers at least one exposed surface of the electrical component and is selectively secured to the first portion, wherein the second portion provides shielding for the electrical component and both the first portion and the second portion include one or more of the signal layers.

10. The flexible shielding circuit according to claim 9, wherein the second portion of the flexible circuit is folded over the electrical component.

11. The flexible shielding circuit according to claim 10, wherein the second portion of the flexible circuit is bent in a manner such that a part of the second portion forms a loop, wherein ends of the loop are joined by a conductive bond.

12. The flexible shielding circuit according to claim 9, further comprising an adhesive that secures the second portion to the exposed surface of the electrical component.

13. The flexible shielding circuit according to claim 9, wherein there is a gap between the exposed surface of the electrical component and the second portion that covers the exposed surface.

14. The flexible shielding circuit according to claim 9, wherein signals are routed from one part of the electrical component to another part of the electrical component or some other electrical component through the signal layer in the second portion.

15. The flexible shielding circuit according to claim 14, wherein the first portion of the flexible circuit includes a ground plane and the signals are routed through the signal layer of the second portion without interfering with the ground plane in the first portion.

16. The flexible shielding circuit according to claim 9, further comprising another electrical component mounted on top of the second portion of the flexible shielding circuit.

17. The flexible shielding circuit according to claim 9, wherein the flexible shielding circuit is part of a mobile communications unit having a transmitter or a receiver or both.

18. The flexible shielding circuit according to claim 9, wherein at least a portion of the flexible circuit includes an outer, non-conductive layer that surrounds the signal layers.
